(19) United States
(12) Patent Application Publication
(10) Pub. No.: US 2014/0366250 A1
(43) Pub. Date: Dec. 18, 2014

(54) Shielded Secure Pocket

(71) Applicant: Sofio's, L.L.C., Vienna, VA (US)

(72) Inventors: Michael Barone, Vienna, VA (US); Oyungerel Bagmid, Vienna, VA (US)

(73) Assignee: Sofio's, L.L.C., Vienna, VA (US)

(21) Appl. No.: 14/273,048

(22) Filed: May 8, 2014

Related U.S. Application Data
(60) Provisional application No. 61/835,097, filed on Jun. 14, 2013.

(51) Int. Cl. A41D 27/20; H05K 9/00

(52) U.S. Cl. CPC A41D 27/205; A41D 27/201; H05K 9/0071; H05K 9/0073
USPC 2/251; 2/247; 2/252

(57) ABSTRACT

A pocket incorporated into a garment or accessory provides shielding for wireless communication and other electronic devices and allows insertion and extraction of a wireless communication or other electronic device from the pocket in a simple and natural motion while avoiding compromise of the fit, appearance or function of the garment or accessory.

### CROSS-REFERENCE TO RELATED APPLICATIONS

This application claims priority of U.S. Provisional Patent Application Ser. No. 61/835,097, Filed Jun. 14, 2013, which is hereby fully incorporated by reference.

### FIELD OF THE INVENTION

The present invention generally relates to shielding for wireless communication devices and, more particularly, to a pocket for a garment or accessory which can provide shielding for such devices.

### BACKGROUND OF THE INVENTION

Wireless communication devices and cellular telephones, in particular, have become very popular in recent years to the point of becoming substantially ubiquitous in the United States and many other countries. As a safety measure, many, if not all, currently marketed cellular telephones, often referred to as, simply cell phones, are also equipped with global positioning system (GPS) capabilities so that the cell phone, itself, can be used to locate a person that may have placed an emergency call but who may be incapable of verbally communicating with emergency personnel. Other applications may involve tracking of lost or stolen property which may include the cell phone, itself, and the like.

This capability, while virtually indispensable in an actual emergency and highly useful in connection with an incident involving theft or the like has two principal disadvantages. First, to support the above safety function the GPS capability must remain activated to receive GPS signals from satellites and/or cell towers even when the cell phone is turned off. This continuous activation reduces the useful period of operation for a given battery charging operation. Second, the cell phone can be individually tracked to within a relatively short distance of its actual location without the knowledge of the person carrying the cell phone. Such a tracking capability is considered by many cell phone users to be an invasion of their privacy, particularly when performed commercially within commercial establishments to, for example, obtain information that may be used to target advertising and other marketing efforts to them individually. The capability to track individual persons can also be a source of danger to military, intelligence and law enforcement personnel and others employed in similar activities. This tracking capability can only be defeated in cell phones of current design by removing the cell phone battery from the cell phone; a process which is awkward and time-consuming.

Additional vulnerability may be encountered with devices continuously connected to wireless networks using radio frequencies such as so-called Wi-Fi and Bluetooth™. It is known, for example, that protocols used in some of these communication links are susceptible to interception and/or hacking and may cause vulnerability of other electronic devices connected thereto.

Containers are currently commercially available to provide shielding and/or electronic protection for wireless communication devices such as cell phones, tablet computers, radio frequency identification devices (RFIDs), smart cards and the like. These containers may be of a rigid construction or may be made of materials such as fabric and/or leather and are asserted to have acceptable performance and provide such benefits as the capability of avoidance of incoming calls (and ring tones) as well as isolation of the GPS capability. However, such containers that are currently commercially available are separate devices that can be separated from a user or misplaced and are somewhat bulky such that they generally must be carried in a purse or briefcase or the like. Containers that can be carried in an ordinary pocket of a garment impair the fit and appearance of the garment. Further, to insert or extract a wireless communication device, the container must be retrieved from wherever it is carried, opened and the communication device inserted or extracted which is also time consuming and awkward and, perhaps more importantly, conveys the use of such a container to others in the vicinity. Moreover, such containers may not be effective to provide shielding if not closed in the intended manner which might not be evident to the user and thus lead to a false sense of security in regard to shielding or GPS tracking.

### SUMMARY OF THE INVENTION

It is therefore an object of the present invention to provide a shielding arrangement for wireless communication devices in the form of a pocket that may be integrally formed in a garment or accessory in such a way that the fit and appearance of the garment are not impaired of the bulk or shape of an accessory such as a handbag or case is not significantly affected.

It is another object of the invention to provide a shielding pocket in a garment or accessory such that a wireless communication device may be easily inserted and retrieved in a manner that does not draw attention to the insertion or extraction and which can be reliably closed around the wireless communication device easily and effectively in a manner that is natural to the wearing of the garment or use of the accessory.

It is a further object of the invention to provide a secure shielding pocket having a closure arrangement that facilitates secure and effective closure to ensure the shielding function while impeding closure in a manner that is incorrect or would compromise the shielding function.

In order to achieve these and other objects of the invention a secure pocket providing shielding for an electronic device placed within it is provided comprising first and second layers of flexible shielding material which are overlaid and joined at all but one edge, one edge of the first layer of flexible conductive material extending beyond the one edge of the second layer of material, and a region for an attachment to a garment or accessory at a location spaced from the one edge of the second layer of material.

In accordance with another aspect of the invention, a garment or accessory including a secure pocket is provided, said secure pocket comprising first and second layers of flexible shielding material which are overlaid and joined at all but one edge, one edge of the first layer of flexible conductive material extending beyond one edge of the second layer of material, and an attachment to the garment or accessory at a location spaced from the one edge of the second layer of material.

### BRIEF DESCRIPTION OF THE DRAWINGS

The foregoing and other objects, aspects and advantages will be better understood from the following detailed description of a preferred embodiment of the invention with reference to the drawing, in which:

FIG. 1 is a partially cut-away, partially exploded isometric view of a shielded secure pocket as installed in a garment or accessory in accordance with the invention, and

FIGS. 2 and 3 are views of the secure pocket as incorporated into a garment or accessory with the secure pocket closed and open, respectively.

### DETAILED DESCRIPTION OF A PREFERRED EMBODIMENT OF THE INVENTION

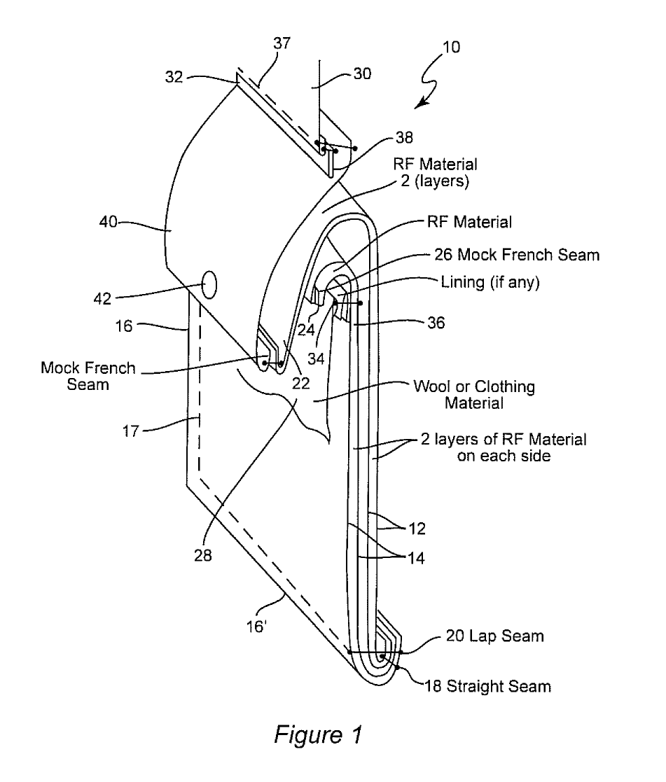

Referring now to the drawing, FIG. 1, there is shown an isometric view of the shielded secure pocket in accordance with the invention. The illustration is partially cut-away and expanded or exploded to more clearly illustrate the construction of seams and installation in a garment or accessory (hereinafter sometimes collectively referred to simply as “garment” since many accessories can be regarded as being worn) which are important to the proper functioning of the shielded secure pocket. Proper functioning of the shielded pocket should be understood to include not only the shielding function but also the ability to insert or extract a wireless communication device in a natural, simple and rapid motion as well as providing for proper closure of the secure pocket and the avoidance of having the pocket compromising the function, fit or appearance of the garment or accessory of which it forms an integral part.

The pocket 10 in accordance with the invention is preferably formed of two overlaid pairs 12, 14, of layers of material with seams on three sides or a pair of single layers of material folded upon itself (e.g. at edge 16 or 16′) with seams (e.g. 17) at two sides. A single layer or ply of material may be sufficient for some applications rather than either or both of the two pairs of layers or plies illustrated. FIG. 1 is thus considered as being equally illustrative of any of these constructions. The material is preferably a commercially available fabric incorporating silver and/or nickel (or alloys of either or both or other conductive or magnetic materials), possibly as a coating, in a preferably very thin and flexible rip-stop nylon and maintains conductive and magnetic properties even after washing and/or abrasion. Such materials are commercially available.

Where seams 17 are formed at edges of the pocket, a straight seam 18 is preferably formed and that seam and the material folded over and secured by a so-called lap seam 20. This construction avoids any gap remaining in the seam and results in complete closure of the pocket on three sides. Seams can be sewn with a thread having similarly conductive and magnetic properties which is also commercially available but such a thread material is not critical to the successful practice of the invention or preferred as long as the stitches are small and tight. Layer(s) 12 is configured to be longer than layer(s) 14 so that a flap-like extension 22 is formed that extends beyond the edge 24 of layer(s) 14. The free edge of the material of layer pair 14 are preferably joined by a so-called mock French seam 26 formed by making a straight seam and then inverting the seamed structure (e.g. similar to turning the seamed object inside-out) so that the seam is concealed between folded ends of the material. Other types of seams may be used as will become apparent to those skilled in the art as long as no gap between layers of material is allowed to remain at the seam and no gap is likely to be created by routine use or wear of the garment or accessory or a secure pocket incorporated therein. The preferred seam structures described above are particularly robust in this regard and are very much preferred for that reason.

The dimensions of the pocket formed as described above are not critical to the practice of the invention or its effectiveness to isolate electrical and magnetic fields inside and outside of the pocket from each other. In general, it is preferred to make the pocket of a width at least one inch wider and of a depth about one and one-half inches deeper than the object(s) to be placed therein in order to accommodate the thickness of the object(s), to limit distortion of the garment by the object(s) while facilitating access to the object(s) (e.g. placement in or removal from the pocket) and/or folding of layers 12 and 14 to close the secure pocket as will be described in greater detail below.

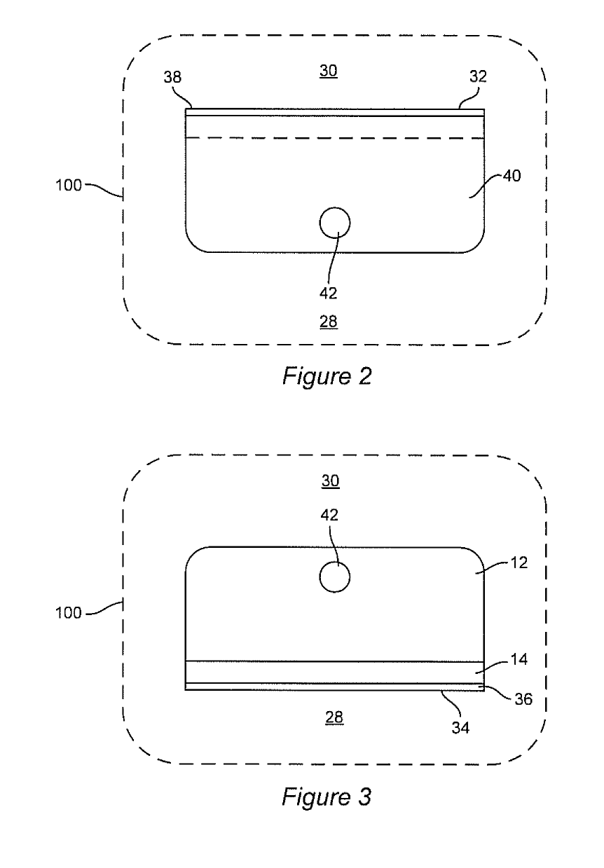

Referring also now to FIGS. 2 and 3, the pocket formed and constructed as described above is preferably incorporated into a garment by forming a slit-shaped opening between portions 32, 34 of a layer 100 of the garment or accessory (which are schematically represented thereby) such as in an outer layer or lining of the garment or accessory or even in a single layer of material in any arbitrary portion of the garment or accessory (e.g. material comprising any exposed surface), such as between regions 28 and 30. Layer(s) 14 is preferably joined to region 28 about one-half inch or more from the end of the layer or layer pair 14. A lapped seam 34 in region 28 is also preferred for this purpose and may optionally include a piping element 36 and/or attachment to lining or surface material or both which may be achieved in the same structure or separately formed.

In regard to attachment of layer or layer pair 12 to a garment, a flap 40 is preferably attached to extend the material region 30 beyond the attachment at 34 as described above; preferably using a lap seam 37 in the region 30 and an optional piping element 38. The end of the flap is preferably attached to the end of layer or layer pair 12 with a mock French seam. One or more closures, schematically depicted at 42, such as a button and button hole or snap closure, hook and loop fabrics (commonly referred to as Velcro™) zipper(s), magnetic closure or the like is provided near the edge of the flap 40. (Both hook and loop and zipper fasteners of materials that provide electromagnetic shielding are commercially available and are preferred to their non-shielding counterparts but are not required for the successful practice of the invention.) It should be appreciated that the extended flap 40 attached to layer or layer pair 12 and the attachment of layer or layer pair 14 to region 28 at a location spaced from the end of layer or layer pair 14 and the securing of closure 42 results in a folding of layers or layer pairs 12 and 14 over themselves as well as over each other so that no gap remains between portions of the material of the secure pocket when flap 40 is in place, even if not fully secured by closure 42. The shape and design of flap 40 are not critical to the successful practice of the invention as long as the size of flap 40 relative to the region of the secure pocket where it is to be attached to material of the garment or accessory causes folding of both layers 12 and 14. Otherwise the design of the flap 40 can be entirely ornamental in nature. Further, when the flap is closed, the secure pocket will be as flat as its contents allow and thus the secure pocket, itself, does not compromise the fit, appearance or function of the garment or accessory while complete enclosure of anything such as a wireless communication device is assured; thus essentially forming a so-called Faraday cage around such a device for providing complete shielding in regard to either incoming or outgoing wireless or GPS communication signals.

In operation, the secure shielded pocket in accordance with the invention allows a wireless communication device to be inserted or extracted in a simple natural motion that is unlikely to draw attention and the cell phone need not be turned off or batteries removed when inserted into the pocket. Messages and calls are not affected in regard to signaling to the caller even though they are not received by the wireless communication device when placed in the secure pocket. Messages and voice mails sent while the cell phone is shielded by the secure pocket are remotely stored in the normal manner and delivered immediately when the cell phone is extracted from the secure pocket and a communication link re-established. This latter function may be useful in preventing calls or ring tones when it is desired that a cell phone make no noise and avoids production of sounds from the cell phone as it is turned off or on as well as avoiding the time delay before a message can be delivered after the cell phone is turned on.

In view of the foregoing, it is seen that the secure pocket in accordance with the invention provides for complete electromagnetic shielding of any electronic device (e.g. smart cards, near-field and Bluetooth™ radio devices, active or passive RFID transponders, passports and the like) and protection from tracking of GPS capabilities of cell phones as well as blocking incoming calls or messages to any wireless communication device inserted into it as well as improved operation (compared to turning a wireless communication device off and on or removal/replacement of batteries as alluded to above) of the wireless communication device. A wireless communication device can be inserted or extracted with a natural and simple motion. Further, a garment (including uniforms, protective gear as well as accessories such as handbags, purses and briefcases as alluded to above) into which the secure pocket is incorporated is not compromised in fit, appearance or function by the secure pocket, itself.

While the invention has been described in terms of a single preferred embodiment, those skilled in the art will recognize that the invention can be practiced with modification within the spirit and scope of the appended claims.

Having thus described my invention, what I claim as new and desire to secure by Letters Patent is as follows:

1. A secure pocket providing shielding for an electronic device placed within it comprising
first and second layers of flexible shielding material which are overlaid and joined at all but one edge,
said one edge of said first layer of flexible conductive material extending beyond said one edge of said second layer of material, and
a region for attachment to a garment or accessory at a location spaced from said one edge of said second layer of material.

2. The secure pocket as recited in claim 1, wherein each of said first and second layers of flexible shielding material comprises two plies of flexible shielding material.

3. The secure pocket as recited in claim 1, wherein said flexible shielding material comprises threads containing or coated with conductive material interwoven into a fabric.

4. The secure pocket as recited in claim 3, wherein said conductive material is silver, nickel or an alloy of silver or nickel.

5. The secure pocket as recited in claim 3, wherein said fabric is rip-stop nylon fabric.

6. The secure pocket as recited in claim 1, further including a flap having an edge attached to material of a garment and an opposite edge attached to said one edge of said first layer of flexible shielding material.

7. The secure pocket as recited in claim 1, wherein said one edge of said first layer of flexible shielding material folds over said one edge of said second layer of said flexible shielding material.

8. The secure pocket as recited in claim 7, wherein folding of said first edge of said first layer of flexible shielding material over said first edge of said second layer of material causes folding of said second layer of flexible shielding material over itself.

9. The secure pocket as recited in claim 1, further including a closure arrangement for securing said first edge of said first layer of flexible shielding material when folded over said first edge of said second layer of flexible shielding material.

10. The secure pocket as recited in claim 9, wherein said closure arrangement is a snap closure.

11. The secure pocket as recited in claim 1, wherein said first and second layers of material are secured together by
a straight seam,
a fold, and
a lap seam securing said fold.

12. The secure pocket as recited in claim 1, wherein said secure pocket is secured to said garment with a mock french seam.

13. The secure pocket as recited in claim 12, wherein said mock french seam includes piping.

14. A garment or accessory including a secure pocket, said secure pocket comprising
first and second layers of flexible shielding material which are overlaid and joined at all but one edge,
said one edge of said first layer of flexible conductive material extending beyond said one edge of said second layer of material, and
an attachment to said garment or accessory at a location spaced from said one edge of said second layer of material.

15. The garment or accessory as recited in claim 14, wherein each of said first and second layers of flexible shielding material comprises two plies of flexible shielding material.

16. The garment or accessory as recited in claim 14, wherein said flexible shielding material comprises threads containing or coated with conductive material interwoven into a fabric.

17. The garment or accessory as recited in claim 16, wherein said conductive material is silver, nickel or an alloy of silver or nickel.

18. The garment or accessory as recited in claim 14, further including a flap having an edge attached to material of a garment or accessory and an opposite edge attached to said one edge of said first layer of flexible shielding material.

19. The garment or accessory as recited in claim 14, wherein said one edge of said first layer of flexible shielding material folds over said one edge of said second layer of said flexible shielding material.

20. A method of providing shielding for an electronic device, said method comprising steps of
forming a slit-shaped opening in a layer of material of a garment or accessory,
inserting a pocket formed of first and second layers of fabric having conductive or magnetic material incorporated therein,
inserting said pocket into said slit-shaped opening,
attaching a flap to one side of said slit-shaped opening,
attaching an end of said first layer of fabric to said flap,
attaching said second layer of fabric to another side of said slit-shaped opening at a location spaced from an end of said second layer of fabric, and
folding said flap over said first layer of fabric such that said end of said first layer of fabric is folded over said second layer of fabric and said end of said second layer of fabric is folded over itself.
